(19) United States
(12) Patent Application Publication
(10) Pub. No.: US 2006/0214271 A1
(43) Pub. Date: Sep. 28, 2006

(54) Device and applications for passive RF components in leadframes

(76) Inventors: Jeremy Loraine, Cottenham (GB); Stephen J. Kovacic, Ottawa (CA)

Correspondence Address: Ralph A. Dowell of DOWELL & DOWELL P.C., 2111 Eisenhower Ave, Suite 406, Alexandria, VA, 22314, US

(21) Appl. No.: 11/086,321

(22) Filed: Mar. 23, 2005

(51) Int. Cl. H01L 23/495

(52) U.S. Cl. 257/666

(57) ABSTRACT

A leadframe and a semiconductor package including such a lead frame, are provided by embodiments of the invention. The leadframe includes a die flag, leads, and a radio frequency (RF) passive component integrally formed into the leadframe. Examples of the RF passive component can be an antenna, such as a spiral or serpentine antenna or one or more transmission lines that can be used as a coupler or filter. The RF passive component can also be tuned to particular frequency values and ranges depending on the particular location of attachment to the RF passive component. The semiconductor package further comprises a semiconductor die and a coupling means with which to connect to the RF passive component to another location on the leadframe, such as the leads and/or the semiconductor die. The semiconductor package may also be encapsulated in a non-conductive material to protect the semiconductor die, coupling means and RF passive component.

### FIELD OF THE INVENTION

The invention relates to integrating passive Radio Frequency (RF) components onto a semiconductor leadframe and applications for which the leadframe can be used.

### BACKGROUND OF THE INVENTION

In the area of wireless communication technology one aspect of research and development emphasis is directed to smaller and less expensive hardware. One of the ways to achieve smaller and less expensive hardware is integration of components so as to reduce a footprint size of the hardware involved, such as printed circuit boards (PCBs) and the components that are located on the PCBs.

Many RF circuits used in wireless communication require filters and other passive device elements such as antennas. In many applications the cost of filters, antennas, and other passive RF devices contribute a significant portion of a total overall cost of a customer solution. In other words, while one might be able to provide low cost integrated circuit components such as transmitters and receivers, the ancillary RF circuit passive devices required to complete a module or system can dominate the total overall cost.

Conventional solutions for providing passive RF device elements in association with integrated circuits result in several disadvantages. One common solution is to let the end manufacturer combine discrete passive RF components with vendor supplied integrated circuits in a manner that is suited to the end manufacturer's particular product. The disadvantage of this solution is that physical space required for certain types of passive RF components at particular frequencies pushes complicated design or redesign into the realm of the end manufacturer. This may result in additional time and money being spent by the end manufacturer in developing necessary components for proper operation of the integrated circuit from the vendor.

Other common solutions include using wirebonds to implement passive RF components or aspects of passive RF components and placing passive RF devices directly on a semiconductor die.

A vendor driven solution for providing customers and/or end manufacturers with suitable passive RF components in close proximity to semiconductor circuits is desirable and would result in economic benefit for both vendors and end manufacturers.

### SUMMARY OF THE INVENTION

One aspect of the invention is to use the leadframe construction flow to construct various passive RF device elements concurrently with the leadframe and die flag. As a result the various RF device elements described herein are formed as an integral part of the leadframe structure.

The leadframe may be formed to support a plurality of RF device elements while concurrently supporting and providing connectivity to one or more semiconductor die.

According to a first aspect of the invention, there is provided a semiconductor leadframe comprising a die flag, leads and an antenna, wherein the antenna is integrally formed into the leadframe.

According to an embodiment of the first aspect of the invention, the antenna is electrically isolated from the die flag and leads of the leadframe.

According to another embodiment of the first aspect of the invention, the antenna is electrically coupled to a lead of the leadframe.

According to another embodiment of the first aspect of the invention, the antenna is any one of a group consisting of a spiral antenna, a serpentine antenna, a patch antenna and a straight-line antenna.

According to a second aspect of the invention, there is provided a semiconductor leadframe comprising a die flag, leads and a coupler comprising two or more transmission lines, wherein the coupler is integrally formed into the leadframe.

According to an embodiment of the second aspect of the invention, at least one transmission line of the two or more transmission lines is electrically isolated from the die flag and leads of the leadframe.

According to another embodiment of the second aspect of the invention, at least one transmission line of the two or more transmission lines is electrically coupled to a lead of the leadframe.

According to another embodiment of the second aspect of the invention, the two or more transmission lines comprise two substantially parallel transmission lines, and the coupler is adapted to couple at least a portion of RF energy supplied to a first transmission line into a second transmission line.

According to another embodiment of the second aspect of the invention, the two or more transmission lines comprise three substantially parallel transmission lines, and the coupler is adapted to couple at least a portion of RF energy supplied to a first transmission line into a second transmission line and to couple at least a portion of RF energy from the second transmission line into a third transmission line.

According to another embodiment of the second aspect of the invention, the coupler is as a frequency selective filter for filtering a signal coupled into a first transmission line and coupled out of a second transmission line.

According to a third aspect of the invention, there is provided a semiconductor leadframe comprising a die flag, leads and a quarter wavelength transmission line, wherein the transmission line is integrally formed into the leadframe.

According to an embodiment of the third aspect of the invention, the transmission line is electrically isolated from the die flag and leads of the leadframe.

According to an embodiment of the third aspect of the invention, the transmission line is electrically coupled to a lead of the leadframe.

According to another embodiment of the third aspect of the invention, the semiconductor leadframe further comprises a second die flag located at a first end portion of the quarter wavelength transmission line and a third die flag is located at a second end portion of the quarter wavelength transmission line.

According to a fourth aspect of the invention, there is provided a semiconductor package comprising: a leadframe according to the first aspect of the invention; a semiconductor die located on the die flag; and a coupling means for coupling to the antenna.

According to an embodiment of the fourth aspect of the invention, the antenna is electrically isolated from the die flag and leads of the leadframe, and the coupling means electrically couples the antenna to another location on the leadframe.

According to another embodiment of the fourth aspect of the invention, the coupling means electrically couples the antenna to another location on the leadframe.

According to another embodiment of the fourth aspect of the invention, the antenna is any one of a group consisting of a spiral antenna, a serpentine antenna, a patch antenna and a straight-line antenna.

According to a fifth aspect of the invention, there is provided a semiconductor package comprising: a leadframe according to the second aspect of the invention; a semiconductor die located on the die flag; and a coupling means for coupling to the coupler.

According to an embodiment of the fifth aspect of the invention, at least one transmission line of the two or more transmission lines is electrically isolated from the die flag and leads of the leadframe, and the coupling means electrically couples the at least one transmission line to another location on the leadframe.

According to another embodiment of the fifth aspect of the invention, wherein the coupling means electrically couples at least one transmission line to another location on the leadframe.

According to another embodiment of the fifth aspect of the invention, the coupler is a frequency selective filter for filtering a signal coupled into a first transmission line and coupled out of a second transmission line.

According to another embodiment of the fourth aspect of the invention, wherein the antenna is adapted to be tuned to a particular frequency or frequency range as a function of a location of attachment of the coupling means to the antenna.

According to another embodiment of the fifth aspect of the invention, wherein at least one transmission line of the two or more transmission lines is adapted to be tuned to a particular frequency or frequency range as a function of a location of attachment of the coupling means to the at least one transmission line.

According to another embodiment of the fifth aspect of the invention, at least one transmission line of the two or more transmission lines is adapted to be tuned to provide a certain coupling quality as a function of a location of attachment of the coupling means to the at least one transmission line.

According to another embodiment of the fourth aspect of the invention, the semiconductor package further comprises a non-conductive material to encapsulate the semiconductor die, the coupling means and the antenna of the leadframe.

According to another embodiment of the fifth aspect of the invention, the semiconductor package further comprises a non-conductive material to encapsulate the semiconductor die, the coupling means and the coupler of the leadframe.

According to a sixth aspect of the invention, there is provided a method for tuning an antenna in a leadframe, the method comprising: integrally forming a leadframe comprising a die flag, leads and the antenna; and coupling to the antenna at a location on the antenna that provides for operation at a particular frequency or frequency range.

According to a seventh aspect of the invention, there is provided a method for tuning at least one transmission line of two or more transmission lines forming a coupler in a leadframe, the method comprising: integrally forming a leadframe comprising a die flag, leads and the two or more transmission lines; and coupling to the at least one transmission line at a location on the at least one transmission line that provides for operation at a particular frequency or frequency range.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Preferred embodiments of the invention will now be described with reference to the attached drawings in which:

FIG. 1 is a top view schematic diagram of a conventional leadframe;

FIG. 2A is a top view schematic diagram of a leadframe according to an embodiment of the invention having a serpentine antenna;

FIG. 2B is a top view schematic diagram of a leadframe according to an embodiment of the invention having a substantially coil-shaped antenna;

FIG. 2C is a top view schematic diagram of a leadframe according to an embodiment of the invention having a patch antenna;

FIG. 3A is a top view schematic diagram of a leadframe according to an embodiment of the invention having a pair of transmission lines;

FIG. 3B is a top view schematic diagram of a leadframe according to an embodiment of the invention having three transmission lines;

FIG. 4 is a top view schematic diagram of a leadframe according to an embodiment of the invention having a single transmission line;

FIG. 5 is a schematic diagram of an example application for a leadframe according to an embodiment of the type shown in FIG. 4; and

FIG. 6 is a cross section of the leadframe according to the embodiment of FIG. 2A with the leadframe mounted on a printed circuit board.

### DETAILED DESCRIPTION OF THE PREFERRED EMBODIMENTS

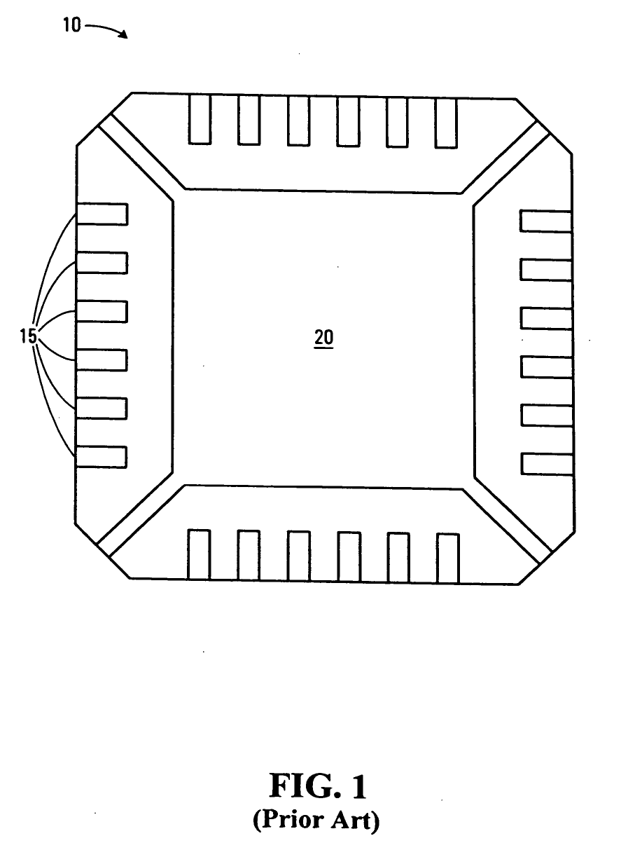

FIG. 1 illustrates a top view schematic of a conventional leadframe. The leadframe 10 has leads 15 positioned about the periphery of the leadframe 10. The leadframe also has a die flag 20, occupying a portion of the center area of the leadframe. The die flag 20 is an area upon which a semiconductor die (not shown) is mounted on the leadframe 10.

The semiconductor die can be mounted on the die flag 20 of the leadframe 10 in any number of ways known to those skilled in the art, for example attaching by epoxy, soldering or spot welding. The semiconductor die includes contact pads for providing an electrical connection to or from the semiconductor die. Electrical connectivity between the semiconductor die contact pads and the leadframe 10 can be implemented using traditional and well-known wirebonding techniques.

The leads 15 and the die flag 20 of the leadframe 10 are typically formed of a similar material and have a uniform thickness throughout the leadframe 10. On the bottom of the leadframe 10, the leads 15 and die flag 20 are left exposed to facilitate electrical connection between the leads 15 and die flag 20 and contact pads or traces on a substrate or a printed circuit board (PCB) to which the leadframe 10 may be attached.

The die flag 20 is used as a grounding contact in some implementations of the conventional leadframe 10.

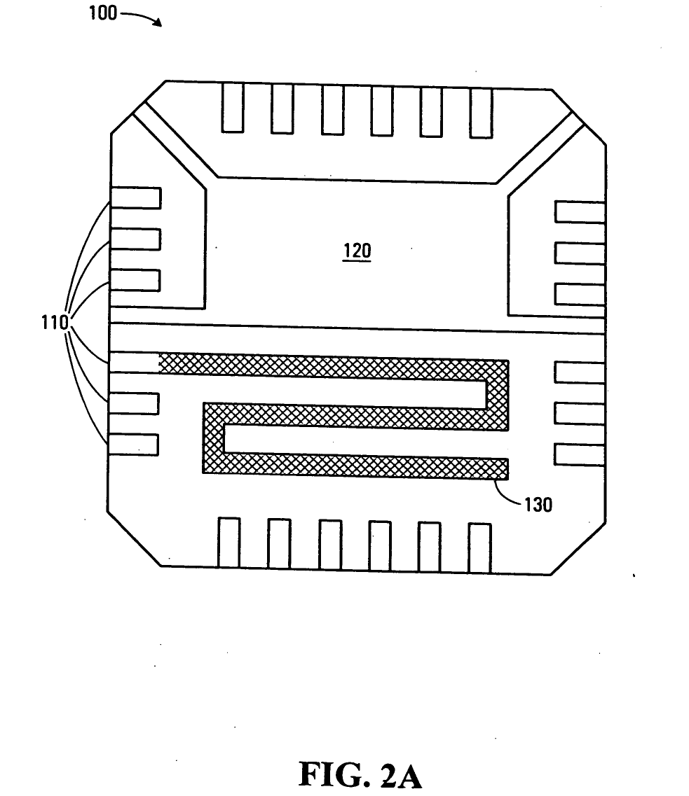

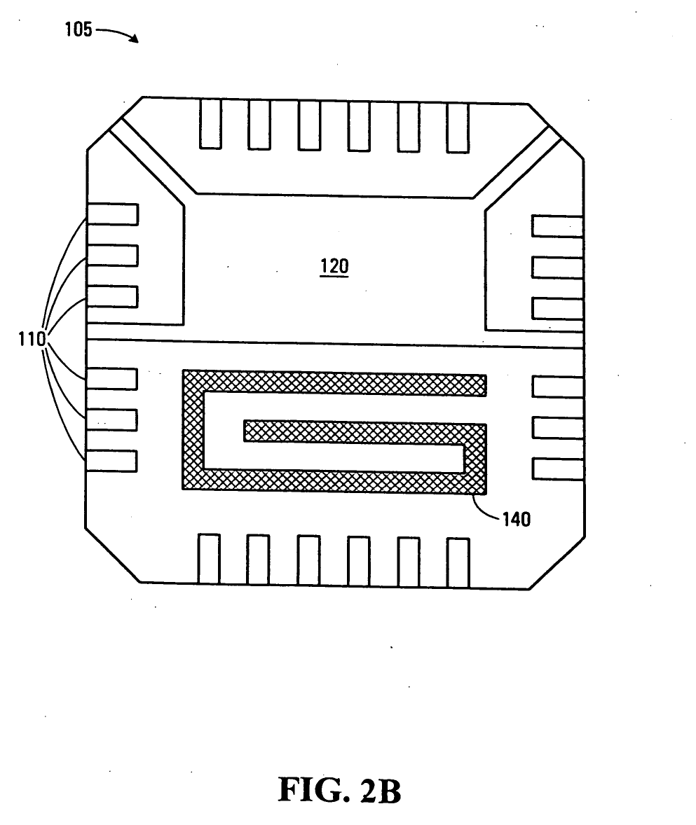

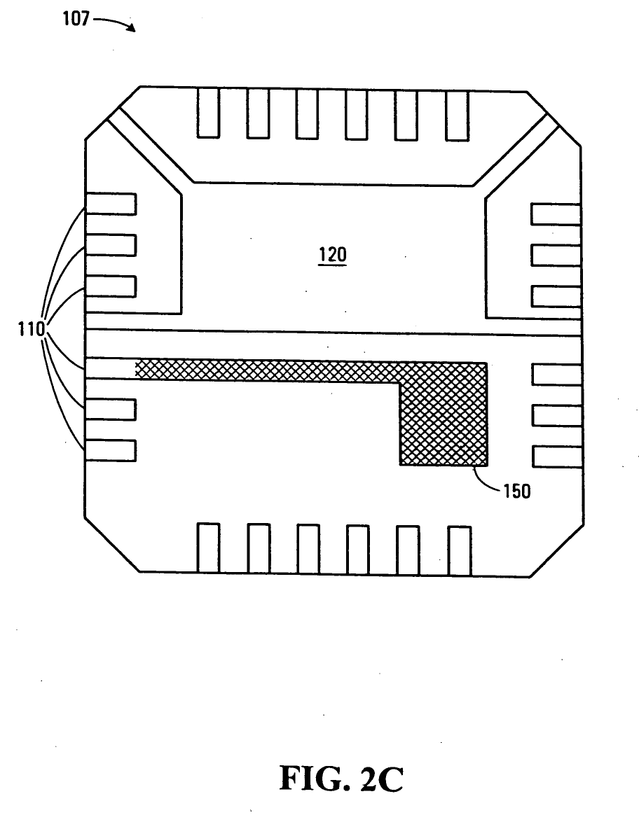

FIG. 2A illustrates a top view schematic of a leadframe 100 according to an embodiment of the invention. The leadframe 100 has leads 110 around the periphery of the leadframe 100 in a similar manner as the conventional leadframe 10 of FIG. 1 and a die flag 120 occupying a portion of the center area of the leadframe 100. The leadframe 100 also has a passive RF component occupying another portion of the center area of the leadframe 100. The passive RF component is a serpentine antenna 130. The antenna 130 is shown connected to a single lead of the leadframe 100 by a coupling portion which is a part of the antenna 130 internal to the leadframe. However, the antenna 130 may be isolated within the leadframe 100, meaning that there are no internal couplings, such as traces, to connect the leads 110 or die flag 120 to the antenna 130. In these embodiments the electrical coupling is applied externally, such as with a wirebond, to the leadframe 100 between the antenna 130 and leads 110 and/or die flag 120 of the leadframe 100.

In a situation where leads do not encompass the entire periphery of the leadframe, the leadframe can also be manufactured to locate the passive RF component on the periphery of the leadframe, instead of or in addition to being located on the portion of the center area of the leadframe.

Electrical connection from a semiconductor die mounted on the die flag 120 of the leadframe 100 to the antenna 130 is typically made by conventional wire bond techniques. For example, a single wire bond connection is made between the antenna 130 and the semiconductor die containing a component using the antenna 130, such as a transmitter or receiver.

If a component, for example a transmitter or receiver, desiring use of the antenna 130 is located off the leadframe 100, an electrical connection can be made to the antenna 130 via the leads 110 of the leadframe 100. In a situation where the antenna 130 is electrically connected to the lead, as shown in FIG. 2A, no additional coupling is needed to provide connection from the off leadframe component to the antenna 130 if the lead is electrically connected to the off leadframe component. If the antenna 130 is electrically isolated from the leads 110 then conventional techniques, such as wirebonding can be used to couple the lead to the antenna 130.

Features such as size of the leadframe 100, the width of a transmission line forming the antenna 130 and available space on the leadframe 100 are all factors that limit the frequency range when designing the antenna 130. In the case of the serpentine antenna 130, the transmission line curves back and forth one or more times to provide a maximum overall length for the antenna. By way of example, an antenna having a length that is between approximately 3.8 mm and 18.8 mm can act as a quarter wavelength antenna for a frequency within the approximate frequency range of 20 GHz to 40 GHz. A quarter wavelength antenna 12 mm long could be implemented by three parallel segments substantially 4 mm long in which a first 4 mm long segment is connected to a second 4 mm long segment by a first end connecting portion and the second 4 mm long segment is connected to a third 4 mm long segment by a second end connecting portion at an end opposite that of the first end connecting portion resulting in the quarter wavelength antenna 12 mm long.

In embodiments in which the antenna 130 is isolated from the leads 110 and die flag 120, as described above, the antenna can be tuned to a particular frequency by attaching a terminating wirebond from a lead 110 or the die flag 120 to any particular location along the length of the antenna 130.

FIG. 6 is a cross sectional view of a leadframe of a type depicted in the embodiment of FIG. 2A, where a leadframe 620 includes a semiconductor die 610 located on a die flag 642 and the leadframe 620 is mounted on a PCB 630. The leadframe 620 includes a die flag 642 and leads 640 around the periphery of the leadframe 620. The leadframe 620 also includes a passive RF component in the form of an antenna 645. The semiconductor die 610 has contact pads 655. The PCB 630 has traces 660 on at least a top surface of the PCB 630 and vias 665 through the PCB 630. A first wire bond 651 is shown connecting one of the contact pads 655 of the semiconductor die 610 to a lead 640 of the leadframe 620. A second wire bond 652 is shown connecting one of the contact pads 655 of the semiconductor die 610 to one end of the antenna 645. The leads 640 are shown to be in electrical contact with the traces 660 of the PCB 630.

The material comprising the antenna, and more generally, any of the additional passive RF components described herein are thinner than the thickness of the leads and die flag. The material forming the passive RF component is fabricated as part of the leadframe manufacturing process and has a thickness which is thinner than the overall base material of the lead frame. This is accomplished by use of one or more etches from the topside and/or backside of the leadframe during manufacturing. Typically, manufacturing techniques that are used are well known in the art. More generally, any desired manufacturing technique can be used which can construct a leadframe with the features described herein.

Typically, the material used in fabricating the passive RF component is metal. However, the material can also be any suitable conductor or semiconductor.

As shown in FIG. 2B, another embodiment of a leadframe 105 having leads 110 around the periphery and a die flag 120, has an antenna 140 that is substantially coil-shaped. The substantially coil-shaped antenna 140 is shown to be isolated from the leads of the leadframe 105 and therefore an external coupling would form the electrical connection between the antenna 140 and another location on the leadframe 105. However, a portion of the antenna 140, for example an end portion as shown in FIG. 2B, may be connected to at least one of the leads of the leadframe 105 by an external coupling such as a wirebond in other embodiments provided by the invention.

FIG. 2C shows a further embodiment provided by the invention in which a leadframe 107 has leads 110 around the periphery, a die flag 120 and an antenna 150. However, in FIG. 2C the antenna 150 is a patch antenna. The leadframe 107 has similar attributes to the leadframes of FIGS. 2A and 2B described above, except for the shape of the antenna 150. The patch antenna 150 is shown to be connected to one of the leads of the leadframe 107, however the patch antenna may be isolated from the leads and an external coupling would form an electrical connection between the antenna 150 and another location on the leadframe 105.

The antenna may also be a straight-line antenna depending on the desired frequency of transmission or receiving, if the leadframe can accommodate a straight-line antenna of the necessary length for the desired frequency of transmission. More generally, the antenna could be any shape known in the art.

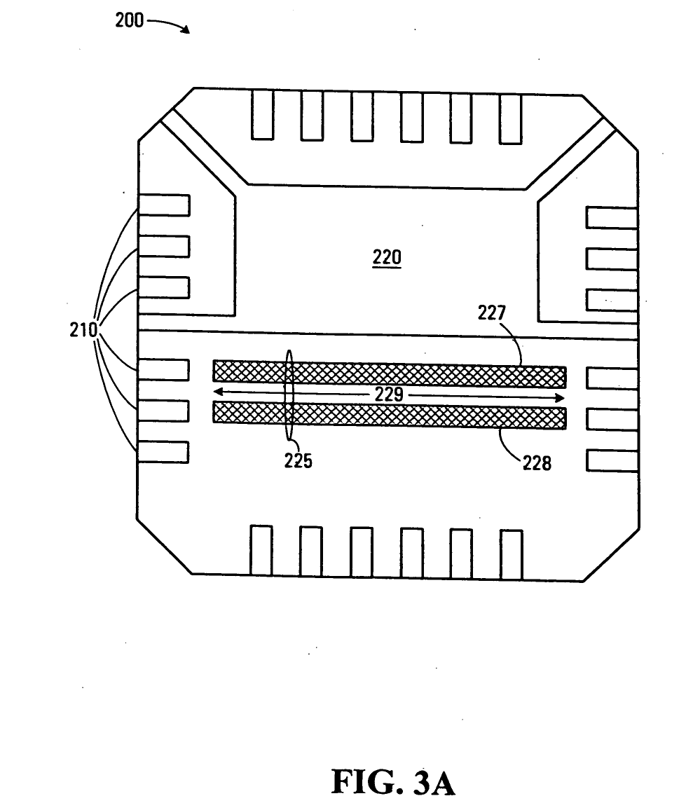

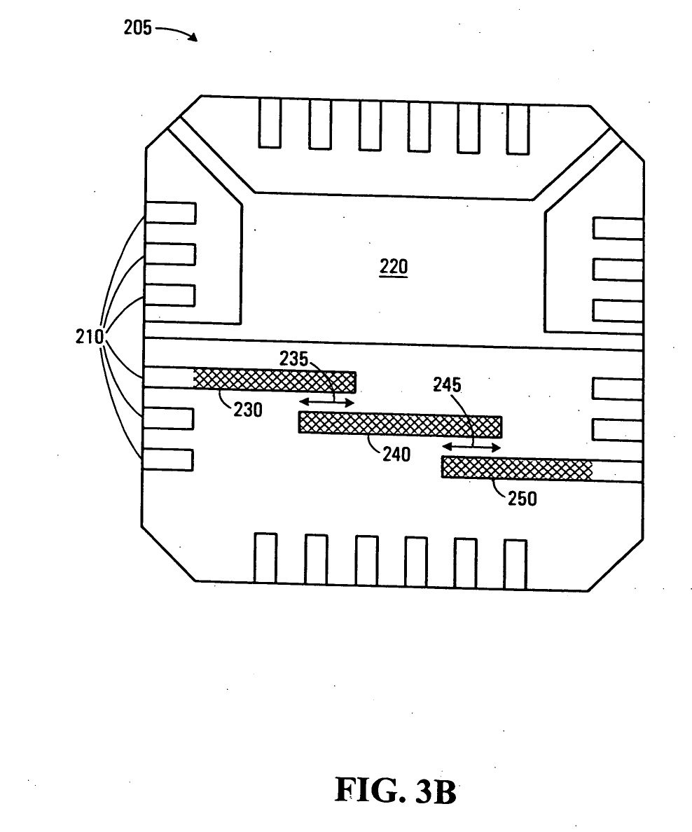

FIG. 3A illustrates a top view schematic of a leadframe 200 according to another embodiment of the invention. The leadframe 200 has leads 210 around the periphery of the leadframe 200 in a similar manner as the conventional leadframe 10 of FIG. 1 and a die flag 220 occupying a portion of the center area of the leadframe 200. In addition, the leadframe 200 also has an integrated passive RF component occupying another portion of the center area of the leadframe 200. The integrated passive RF component is a pair of transmission lines 225 including a first transmission line 227 and a second transmission line 228.

The proximity of the pair of transmission lines 225 to each other allows a portion of RF energy to be coupled between the transmission lines. Depending on dimensions of the transmission lines and other design features known in the art, energy from a certain band of frequencies can be coupled from the first transmission line 227 to the second transmission line 228, or vice versa, thereby enabling a frequency selective RF passive filter for filtering a signal that is supplied to the transmission lines, for example by coupling a signal into the first transmission line 227 and coupling a filtered signal out of the second transmission line 228.

Each of the transmission lines 227,228 of the pair of transmission lines 225 are shown in FIG. 3A to be isolated within the leadframe 200 and not connected to any of the leads 210. In an example in which a semiconductor die located on the die flag 220 is to be electrically connected to the pair of transmission lines 225, electrical connection in the form of a coupling externally applied to the leadframe, is made from a contact pad of the semiconductor die to one end of the first transmission line 227 of the pair of transmission lines 225 by a first wire bond. Electrical connection is made from another contact pad of the semiconductor die mounted on the die flag 220 of the leadframe 200 or a lead around the periphery of the leadframe 200 to one end of the second transmission line 228, opposite to the end of the first transmission line 227, by a second wire bond.

In operation, RF energy is coupled into the first transmission line 227 via the first wirebond. A portion of the RF energy in the first transmission line 227 is coupled into the second transmission line 228 over a length of a side-by-side overlap 229 that occurs between the first and second transmission lines 227,228. The RF energy in the second transmission line 228 is then coupled out of the second transmission line 228 via the second wirebond.

In FIG. 3A, the first and second transmission lines 227,228 are shown to overlap 229 over the entire length of the transmission lines, i.e. they are coextensive. More generally, the length of the overlap can vary in length depending on the coupling requirements desired by the RF passive component designer.

The pair of transmission lines 225 in FIG. 3A are shown to be electrically isolated from the leads 210 of the leadframe 200, but in alternative embodiments provided by the invention one or both ends of the first and/or second transmission lines 227,228 are connected to one or more of the leads 210 of the leadframe 200 by an electrical coupling internal to the leadframe 200, such as a trace, from an end of the first and/or second transmission lines 227,228 to one or more of the leads 210.

In FIG. 3A the leads 210 around the periphery of the leadframe 200 are electrically isolated from the transmission lines 225, but RF energy can be coupled to the transmission lines 225 if the leads are connected to the transmission lines 225, for example using wirebonds to couple RF energy from the leads to the transmission lines 225. As such the integrated passive RF components of the leadframe 200 can be used by components other than those on the semiconductor die mounted on the die flag 220 of the leadframe 200, for example components mounted on the PCB upon which the leadframe 200 is mounted. The leads are either connected to the transmission lines by wirebond, or the transmission lines are connected directly to one or more leads in a manner similar to that described above for other embodiments provided by the inventions.

In alternative embodiments, more than two transmission lines are used in a coupling or filtering process. For example, FIG. 3B shows a leadframe 205 having leads 210 around the periphery, a die flag 220, and also including a first transmission line 230 coupled at one end to a first lead of the leadframe 205, a second transmission line 240 isolated from any of the leads, and a third transmission line 250 coupled at one end to a second lead of the leadframe 205.

In operation, RF energy is coupled into the first transmission line 230 via a first wirebond or directly via connection to a lead of the leadframe 205. A portion of the RF energy in the first transmission line 230 is coupled into the second transmission line 240 over a length of a side-by-side overlap 235 that occurs between the first and second transmission lines 230,240. A portion of the RF energy in the second transmission line 240 is coupled into the third transmission line 250 over a length of a side-by-side overlap 245 that occurs between the second and third transmission lines 240,250. The RF energy in the third transmission line 250 is then coupled out of the third transmission line 250 via a second wirebond or a second lead. As described above, depending on dimensions of the transmission lines, the length of overlap used to couple energy between transmission lines and other design features known in the art, the combination of transmission lines acts as a frequency selective RF passive filter for filtering a signal that is supplied to the transmission lines, for example by coupling a signal into the first transmission line 230 and coupling a filtered signal out of the third transmission line 250. Therefore, filtering of particular frequencies or frequency ranges can be achieved.

Any suitable number of transmission lines can be used to create passive RF filter components with desired filter characteristics.

While the first and third transmission lines 230,250 are shown in FIG. 3B to be connected to leads of the leadframe 205, this is not a necessary feature. In some embodiments one or both of these transmission lines may be electrically isolated from the leads in the same manner as the second transmission line 240. More generally, each of the transmission lines in a multi-transmission line passive RF filter component can be connected to at least one lead of the leadframe 205 or electrically isolated from the leads 210 and die flag 220 of the leadframe 205.

The transmission lines of FIGS. 3A and 3B are shown to be parallel, but the distance between transmission lines may not be constant so as to vary the amount of RF energy coupled between the transmission lines.

The leads around the periphery of the leadframe 205 can be used to directly couple RF energy to the transmission lines if the leads are connected to the transmission lines. Wirebonds can be used to couple RF energy from the leads to the transmission lines if the transmission lines are electrically isolated from the leads. The passive RF components integrated in the leadframe 205 can be used by components other than those on the semiconductor die mounted on the die flag 220 of the leadframe 205, for example components mounted on the PCB upon which the leadframe 205 is mounted, by electrically connecting to the passive RF component using any of the above-described connecting methods.

In embodiments in which one or more transmission line is isolated from leads 210 or the die flag 220, as described above, the one or more transmission line can be tuned to a particular frequency or frequency range by attaching a terminating wirebond from one or more lead or the die flag 220 to any particular location along the length of the one or more transmission line.

In embodiments where at least one end of one or more transmission line is isolated from a lead or the die flag, the one or more transmission line can be tuned to provide certain desirable coupling qualities with one or more other transmission lines by attaching one or more terminating wirebonds at any particular location along the length of the transmission line. For example, with reference to FIG. 3A, a first wirebond could be attached to a location halfway along the first transmission line 227 and a second wirebond could be attached to an end of the second transmission line 228. In this situation the coupling of RF energy occurring between the two transmission lines 227,228 is different than that of the situation described above wherein the wirebonds are located at opposite ends of the transmission lines 227,228.

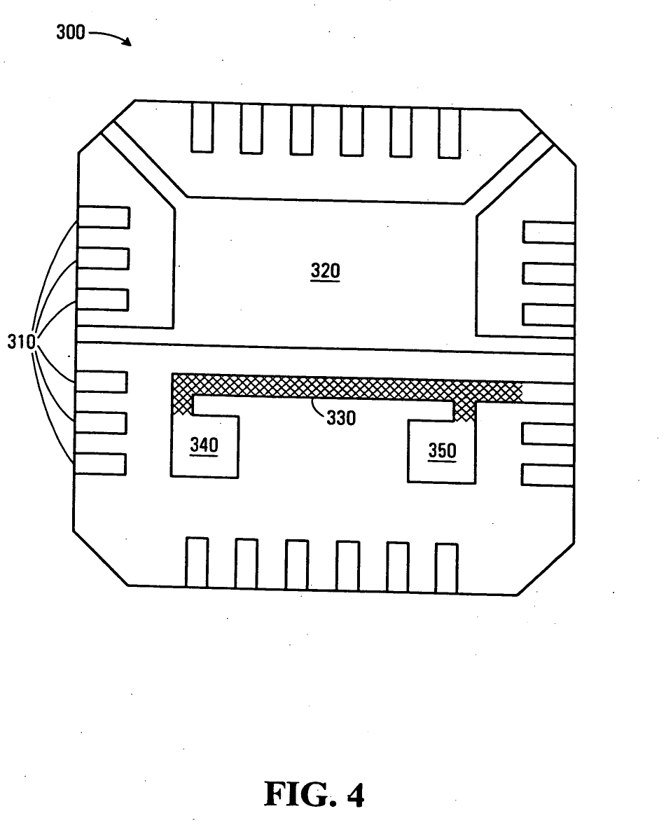

FIG. 4 illustrates a top view schematic of a leadframe 300 according to another embodiment of the invention. The leadframe 300 has leads 310 around the periphery of the leadframe 300 in a similar manner as the conventional leadframe 10 of FIG. 1 and a first die flag 320 occupying a portion of the center area of the leadframe 300. The leadframe 300 also has an integrated passive RF component 330 occupying another portion of the center area of the leadframe 300. The integrated passive RF component is a single transmission line 330. The transmission line 330 is coupled between a second die flag 340 and a third die flag 350 and also coupled to a lead of the leadframe 300.

While one end of the transmission line 330 is shown connected to a lead of the leadframe 300 by a coupling component that is essentially an end portion of the transmission line, this is not a necessary feature. In some embodiments the transmission line 330 is isolated from the leads 310 and/or first die flag 320 at either or both ends of the transmission line 330. In these embodiments a coupling, such as a wirebond, is applied externally to the leadframe between at least one end of the transmission line 330 and leads 310 and/or die flag 320 of the leadframe to create an electrical connection.

In a particularly advantageous embodiment, the length of the single transmission line 330 is a quarter wavelength of a particular frequency.

In some embodiments, the single transmission line 330 is connected to only one of the second or third die flags 340,350. In some embodiments, the single transmission line 330 is not connected to either of the second or third die flags 340,350. In these embodiments it is possible to tune the distance between the second and third die flags 340,350 to a quarter wavelength of a particular frequency by connecting wire bonds from the second and third die flags 340,350, as necessary, to particular and appropriate locations on the single transmission line 330.

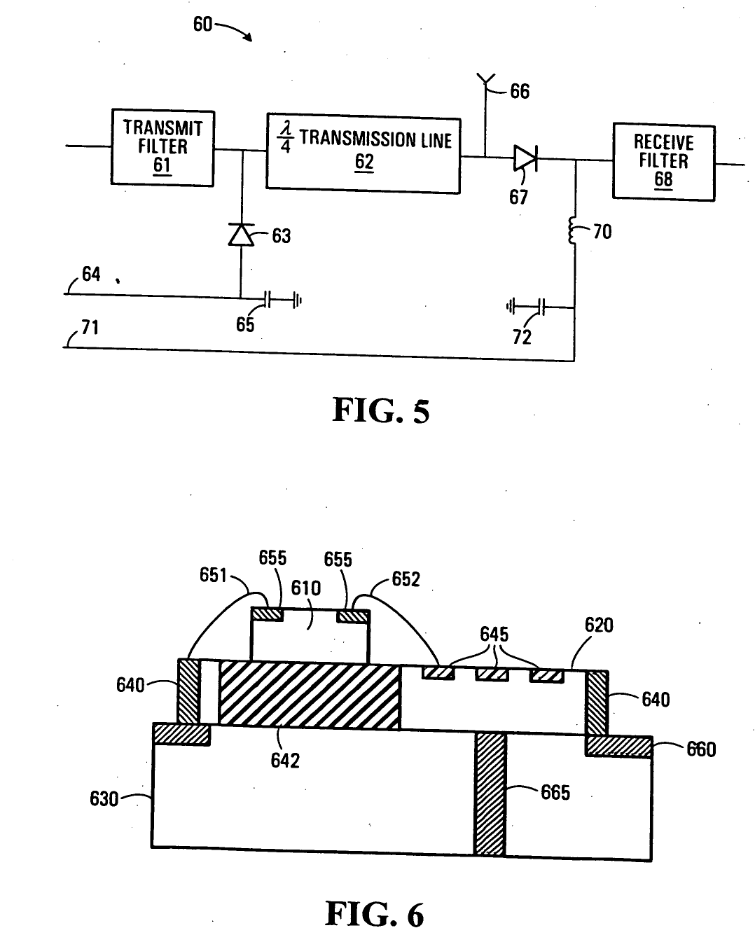

FIG. 5 shows an example schematic diagram of a single quarter wavelength transmission line being used as a component of a transmit/receive switch in a transceiver 60. A transmit filter 61 is coupled to a first end of a quarter wavelength transmission line 62. A cathode end of a first diode 63 is coupled to the first end of the quarter wavelength transmission line 62. An anode end of the first diode 63 is coupled to a first control signal input 64. The anode end of the first diode 63 is also coupled to a first side of a first capacitive element 65. A second side of the first capacitive element 65 is connected to ground.

A second end of the quarter wavelength transmission line 62 is coupled to an antenna 66. The antenna 66 is also coupled to an anode end of a second diode 67. A cathode end of the second diode 67 is coupled to a receive filter 68. A first end of an inductive element 70 is coupled to the cathode end of the second diode 67. A second end of the inductive element 70 is coupled to a second control signal input 71. The second end of the inductive element 70 is also coupled to a first side of a second capacitive element 72. The second side of the second capacitive element 72 is connected to ground.

In operation, the first and second diodes 63,67 are either both conducting or both non-conducting at the same time. When the first and second diodes 63,67 are conducting, an output of the transmit filter 61 is grounded, and a low impedance output of the transmit filter 61 is transformed by the quarter wavelength transmission line 62 into a high impedance at the second end of the quarter wavelength transmission line 62 adjacent to antenna 66. Any signal received by the antenna 66 is blocked from travelling on a transmit side of the transceiver 60 and the signal will only travel in the direction of a low impedance path to the receive filter 68.

When the first and second diodes 63,67 are non-conducting, a receive side of the transceiver 60 is isolated from the antenna 66 by the second diode 67 and the output of the transmit filter 61 is not grounded. As a result the output of the transmit filter 61 passes to the antenna 66 with very low loss. The output of the transmit filter 61 does not pass through a diode before reaching the antenna so losses are very small, maximizing the efficiency of the transceiver 60. The first and second control signal inputs 64,71 are used to ensure that the diodes 63,67 are conducting or non-conducting at the appropriate times.

Referring now to FIG. 4 together with FIG. 5, in the above example the transmit filter 61, first diode 63 and first capacitive element 65 may be located on a semiconductor die attached to the second die flag 340 and electrically connected to the single quarter wavelength transmission line 62 by a wirebond. The receive filter 68, second diode 67, second capacitive element 72 and inductive element 70 may be located on a semiconductor die attached to the third die flag 350 and electrically connected to the single quarter wavelength transmission line 62 by a wirebond.

The transmit and/or receive side components may also be located on a semiconductor die on the first die flag 320 of the leadframe 300 or on a PCB to which the leadframe 300 is mounted. In these situations, the single quarter wavelength transmission line 62 is electrically connected to the transmit and receive side components by a wirebond via contact pads on the semiconductor die or via the leads 310 of the leadframe 300, respectively.

With regard to the antenna 66, the antenna 66 can be an antenna existing elsewhere off the leadframe or it can be an antenna of one of the types described above located on the leadframe.

The above-described example is to be understood as merely one example of how the single quarter wavelength transmission line 330 could be used. Other embodiments that use the single quarter wavelength transmission line 330 and which may or may not include the second and third die flags 340,350 as suggested in the example above are considered to be within the scope of the invention.

Figures of merit associated with each specific passive RF device, for example a quarter wavelength transmission line filter, are controlled by the shape and size of metallization segments incorporated during construction of the leadframe.

In some embodiments, the leadframe is part of a finished package that is fully encapsulated by a non-conductive material. As the passive RF component is integrated within the leadframe, the passive RF component is fully enveloped in the encapsulated package.

Numerous modifications and variations of the present invention are possible in light of the above teachings. It is therefore to be understood that within the scope of the appended claims, the invention may be practised otherwise than as specifically described herein.

1. A semiconductor leadframe comprising a die flag, leads and an antenna, wherein the antenna is integrally formed into the leadframe.

2. The leadframe of claim 1, wherein the antenna is electrically isolated from the die flag and leads of the leadframe.

3. The leadframe of claim 1, wherein the antenna is electrically coupled to a lead of the leadframe.

4. The leadframe of claim 1, wherein the antenna is any one of a group consisting of a spiral antenna, a serpentine antenna, a patch antenna and a straight-line antenna.

5. A semiconductor leadframe comprising a die flag, leads and a coupler comprising two or more transmission lines, wherein the coupler is integrally formed into the leadframe.

6. The leadframe of claim 5, wherein at least one transmission line of the two or more transmission lines is electrically isolated from the die flag and leads of the leadframe.

7. The leadframe of claim 5, wherein at least one transmission line of the two or more transmission lines is electrically coupled to a lead of the leadframe.

8. The leadframe of claim 5, wherein the two or more transmission lines comprise two substantially parallel transmission lines, and the coupler is adapted to couple at least a portion of RF energy supplied to a first transmission line into a second transmission line.

9. The leadframe of claim 5, wherein the two or more transmission lines comprise three substantially parallel transmission lines, and the coupler is adapted to couple at least a portion of RF energy supplied to a first transmission line into a second transmission line and to couple at least a portion of RF energy from the second transmission line into a third transmission line.

10. The leadframe of claim 5, wherein the coupler is a frequency selective filter for filtering a signal coupled into a first transmission line and coupled out of a second transmission line.

11. A semiconductor leadframe comprising a die flag, leads and a quarter wavelength transmission line, wherein the transmission line is integrally formed into the leadframe.

12. The leadframe of claim 11, wherein the transmission line is electrically isolated from the die flag and leads of the leadframe.

13. The leadframe of claim 11, wherein the transmission line is electrically coupled to a lead of the leadframe.

14. The leadframe of claim 11, further comprising a second die flag located at a first end portion of the quarter wavelength transmission line and a third die flag is located at a second end portion of the quarter wavelength transmission line.

15. A semiconductor package comprising:
a leadframe according to claim 1;
a semiconductor die located on the die flag; and
a coupling means for coupling to the antenna.

16. The semiconductor package of claim 15, wherein the antenna is electrically isolated from the die flag and leads of the leadframe, and the coupling means electrically couples the antenna to another location on the leadframe.

17. The semiconductor package of claim 15, wherein the coupling means electrically couples the antenna to another location on the leadframe.

18. The semiconductor package of claim 15, wherein the antenna is any one of a group consisting of a spiral antenna, a serpentine antenna, a patch antenna and a straight-line antenna.

19. A semiconductor package comprising:
a leadframe according to claim 5;
a semiconductor die located on the die flag; and
a coupling means for coupling to the coupler.

20. The semiconductor package of claim 19, wherein at least one transmission line of the two or more transmission lines is electrically isolated from the die flag and leads of the leadframe, and the coupling means electrically couples the at least one transmission line to another location on the leadframe.

21. The semiconductor package of claim 19, wherein the coupling means electrically couples at least one transmission line to another location on the leadframe.

22. The semiconductor package of claim 19, wherein the coupler is a frequency selective filter for filtering a signal coupled into a first transmission line and coupled out of a second transmission line.

23. The semiconductor package of claim 15, wherein the antenna is adapted to be tuned to a particular frequency or frequency range as a function of a location of attachment of the coupling means to the antenna.

24. The semiconductor package of claim 19, wherein at least one transmission line of the two or more transmission lines is adapted to be tuned to a particular frequency or frequency range as a function of a location of attachment of the coupling means to the at least one transmission line.

25. The semiconductor package of claim 19, wherein at least one transmission line of the two or more transmission lines is adapted to be tuned to provide a certain coupling quality as a function of a location of attachment of the coupling means to the at least one transmission line.

26. The semiconductor package of claim 15, further comprising a non-conductive material to encapsulate the semiconductor die, the coupling means and the antenna of the leadframe.

27. The semiconductor package of claim 19, further comprising a non-conductive material to encapsulate the semiconductor die, the coupling means and the coupler of the leadframe.

28. A method for tuning an antenna in a leadframe, the method comprising:
integrally forming a leadframe comprising a die flag, leads and the antenna; and
coupling to the antenna at a location on the antenna that provides for operation at a particular frequency or frequency range.

29. A method for tuning at least one transmission line of two or more transmission lines forming a coupler in a leadframe, the method comprising:
integrally forming a leadframe comprising a die flag, leads and the two or more transmission lines; and
coupling to the at least one transmission line at a location on the at least one transmission line that provides for operation at a particular frequency or frequency range.
